(19) United States
(12) Patent Application Publication
(10) Pub. No.: US 2013/0252367 A1
(43) Pub. Date: Sep. 26, 2013

(54) SYSTEM AND PROCESS FOR FORMING THIN FILM PHOTOVOLTAIC DEVICE

(71) Applicants: Russell Weldon Black, Longmont, CO (US); Shane Patrick Ballard, Louisville, CO (US); Aleksey Boris Bakhtin, Westminster, CO (US)

(72) Inventors: Russell Weldon Black, Longmont, CO (US); Shane Patrick Ballard, Louisville, CO (US); Aleksey Boris Bakhtin, Westminster, CO (US)

(73) Assignee: PrimeStar Solar, Inc., Arvada, CO (US)

(21) Appl. No.: 13/429,545

(22) Filed: Mar. 26, 2012

(51) Int. Cl. H01L 31/18; E03B 7/07

(52) U.S. Cl. 438/57; 137/563; 257/E31.126

(57) ABSTRACT

Systems and processes are disclosed for forming a thin film photovoltaic device. A process includes heating a thin film photovoltaic sub-device to an anneal temperature. The thin film photovoltaic sub-device includes a glass substrate and a transparent conductive oxide deposited on the glass substrate. The process further includes quenching the thin film photovoltaic sub-device with a quenching gas to cool the thin film photovoltaic sub-device to a quenched temperature. The quenching gas includes an inert gas.

### FIELD OF THE INVENTION

The subject matter disclosed herein relates generally to methods and systems for forming thin film photovoltaic devices. More particularly, the subject matter disclosed herein relates generally to methods and systems for heat strengthening glass substrates of thin film photovoltaic devices.

### BACKGROUND OF THE INVENTION

Solar energy systems using cadmium telluride (CdTe) photovoltaic (PV) devices, also known as modules, are generally recognized as the most cost efficient of the commercially available systems in terms of cost per watt of power generated. However, the advantages of CdTe not withstanding, sustainable commercial exploitation and acceptance of solar power as a supplemental or primary source of industrial or residential power depends on the ability to produce efficient PV modules on a large scale and in a cost effective manner.

Certain factors greatly affect the efficiency of CdTe PV modules in terms of cost and power generation capacity. For example, the use of relatively thin glass substrates, which may be top layers, also known as front or sunny-side faces, of the modules during use, can limit the absorption of light energy by the glass substrate in use, allowing more light to reach the PV thin films. Furthermore, thin glass can be less expensive than thick glass. However, the use of relatively thin glass substrates reduces the strength of the glass. As such, the glass may be more susceptible to breakage in use.

Thus, a need exists for a PV module having improved strength in its glass substrate and methods of manufacturing the same.

### BRIEF DESCRIPTION OF THE INVENTION

Aspects and advantages of the invention will be set forth in part in the following description, or may be obvious from the description, or may be learned through practice of the invention.

In one embodiment, a process of forming a thin film photovoltaic device is disclosed. The process includes heating a thin film photovoltaic sub-device to an anneal temperature. The thin film photovoltaic sub-device includes a glass substrate and a transparent conductive oxide deposited on the glass substrate. The process further includes quenching the thin film photovoltaic sub-device with a quenching gas to cool the thin film photovoltaic sub-device to a quenched temperature. The quenching gas includes an inert gas.

In another embodiment, a system for forming a thin film photovoltaic device is disclosed. The system includes a chamber generally sealed from an external environment. The system further includes a quenching system supplying a quenching gas to the chamber to quench a thin film photovoltaic sub-device supported within the chamber. The quenching system includes a manifold assembly. At least a portion of the manifold assembly is disposed within the chamber and defines at least one outlet for the quenching gas to flow therethrough into the chamber. The quenching gas includes an inert gas.

The chamber further includes a quenching system supplying a quenching gas to the chamber to quench a glass substrate supported within the chamber. The quenching system includes a manifold assembly. At least a portion of the manifold assembly is disposed within the chamber and defines at least one outlet for quenching gas to flow therethrough into the chamber.

These and other features, aspects, and advantages of the present invention will become better understood with reference to the following description and appended claims, or may be obvious from the description or claims, or may be learned through practice of the invention.

### BRIEF DESCRIPTION OF THE DRAWINGS

A full and enabling disclosure of the present invention, including the best mode thereof, is set forth in the specification, which makes reference to the appended drawings, in which:

FIG. 1 is a plan view of a system for forming a thin film PV device according to one embodiment of the present disclosure;

FIG. 2 is a perspective view of a quenching apparatus according to one embodiment of the present disclosure;

FIG. 3 is a cross-sectional view of a quenching apparatus according to one embodiment of the present disclosure;

FIG. 4 is a top perspective view of a manifold assembly of a quenching apparatus according to one embodiment of the present disclosure;

FIG. 5 is a bottom perspective view of a manifold assembly of a quenching apparatus according to one embodiment of the present disclosure; and,

FIG. 6 is a cross-sectional view of a CdTe PV module according to one embodiment of the present disclosure.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment, can be used with another embodiment to yield a still further embodiment. Thus, it is intended that the present invention encompass such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless otherwise stated. Thus, these terms are simply describing the relative position of the layers to each other and do not necessarily mean “on top of” since the relative position above or below depends upon the orientation of the device to the viewer.

Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

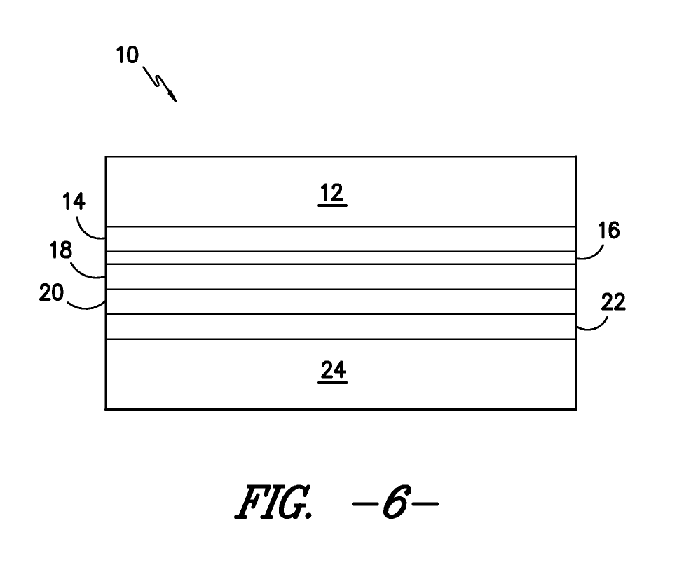

FIG. 6 represents an exemplary CdTe PV module 10 that can be made at least in part according to system and method embodiment described herein. The module 10 includes a top sheet of glass as the substrate 12, which may be a high-transmission glass (e.g., high transmission borosilicate glass), low-iron float glass, or other highly transparent glass material. The glass is generally thick enough (e.g., from about 0.5 mm to about 10 mm thick) to provide support for the subsequent film layers, and is substantially flat to provide a good surface for forming the subsequent film layers.

A transparent conductive oxide (TCO) layer 14 is shown on the substrate 12 of the module 10 in FIG. 6. The TCO layer 14 allows light to pass through with minimal absorption while also allowing electric current produced by the module 10 to travel sideways to opaque metal conductors (not shown). The TCO layer 14 can have a thickness between about 0.1 μm and about 1 μm, for example from about 0.1 μm to about 0.5 μm, such as from about 0.25 μm to about 0.35 μm. The TCO may in exemplary embodiments comprise or consist of cadmium stannate, cadmium tin oxide, or any other suitable TCO.

The TCO layer 14 can be deposited on the substrate 12 by sputtering, chemical vapor deposition, spray pryolysis, or any other suitable deposition method. In particular embodiments, the TCO layer 14 is formed by sputtering (e.g. DC sputtering or RF sputtering) on the substrate 12. For example, the TCO layer 14 can be deposited using a DC sputtering method by applying a DC current to a metallic source material (e.g., elemental zinc, elemental tin, or a mixture thereof) and sputtering the metallic source material onto the substrate 12 in the presence of an oxidizing atmosphere (e.g., O₂ gas).

A resistive transparent buffer (RTB) layer 16 is shown on the TCO layer 14. This layer 16 is generally more resistive than the TCO layer 14 and can help protect the module 10 from chemical interactions between the TCO layer 14 and the subsequent layers during processing of the module 10. In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 μm and about 0.2 μm, for example from about 0.1 μm to about 0.15 μm. In particular embodiments, the RTB layer 16 can include, for instance, a combination of zinc oxide (ZnO) and tin oxide (SnO₂), and is referred to as a zinc-tin oxide (“ZTO”) layer 16.

The ZTO layer 16 can be deposited by sputtering, chemical vapor deposition, spraying pryolysis, or any other suitable deposition method. In particular embodiments, the ZTO layer 16 is formed by sputtering (e.g. DC sputtering or RF sputtering) on the TCO layer 14. For example, the layer 16 can be deposited using a DC sputtering method by applying a DC current to a metallic source material (e.g., elemental zinc, elemental tin, or a mixture thereof) and sputtering the metallic source material onto the TCO layer 14 in the presence of an oxidizing atmosphere (e.g., O₂ gas).

A cadmium sulfide (“CdS”) layer 18 is shown on ZTO layer 16 of the module 10 of FIG. 6. The CdS layer 18 is a n-type layer that generally includes cadmium sulfide but may also include other materials, such as zinc sulfide, cadmium zinc sulfide, etc., and mixtures thereof, as well as dopants and other impurities. The CdS layer 18 may include oxygen up to about 25% by atomic percentage, for example from about 5% to about 20% by atomic percentage. The CdS layer 18 can have a wide band gap (e.g., from about 2.25 eV to about 2.5 eV, such as about 2.4 eV) in order to allow most radiation energy (e.g., solar radiation) to pass therethrough. As such, the cadmium sulfide layer 18 is considered to be a transparent (or “window”) layer in the module 10.

The CdS layer 18 can be formed by sputtering, chemical vapor deposition, chemical bath deposition, or any other suitable deposition method. In one particular embodiment, the CdS layer 18 is formed by sputtering (e.g., radio frequency (RF) sputtering) onto the RTB layer 16, and can have a thickness that is less than about 0.1 μm. This decreased thickness of less than about 0.1 μm reduces absorption of radiation energy by the CdS layer 18, effectively increasing the amount of radiation energy reaching the underlying CdTe layer 20.

A CdTe layer 20 is shown on the CdS layer 18 in the exemplary module 10 of FIG. 6. The layer 20 is a p-type layer that generally includes cadmium telluride (CdTe), but may also include other materials. As the p-type layer of the module 10, the CdTe layer 20 is the photovoltaic layer that interacts with the CdS layer 18 (i.e., the n-type layer) to produce current from the absorption of radiation energy by absorbing the majority of the radiation energy passing into the module 10 due to its high absorption coefficient and creating electron-hole pairs. The CdTe layer 20 can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the CdTe layer 20) across the junction to the n-type side (i.e., the CdS layer 18) and, conversely, holes may pass from the n-type side to the p-type side. Thus, the p-n junction formed between the CdTe layer 18 and the CdTe layer 20 forms a diode in which the charge imbalance leads to the creation of an electric field spanning the p-n junction. Conventional current is allowed to flow in only one direction and separates the light induced electron-hole pairs.

The cadmium telluride layer 20 can be formed by any known process, such as vapor transport deposition, chemical vapor deposition (CVD), spray pyrolysis, electro-deposition, sputtering, close-space sublimation (CSS), etc. In particular embodiments, the CdTe layer 20 can have a thickness between about 0.1 μm and about 10 μm, such as from about 1 μm and about 5 μm.

A back contact layer 22 generally serves as the back electrical contact, in relation to the opposite TCO layer 14 serving as the front electrical contact. The back contact layer 22 can be formed on, and in one embodiment is in direct contact with, the CdTe layer 20. The back contact layer 22 is suitably made from one or more highly conductive materials, such as elemental nickel, chromium, copper, tin, aluminum, gold, silver, technetium or alloys or mixtures thereof. Additionally, the back contact layer 22 can be a single layer or can be a plurality of layers. In one particular embodiment, the back contact layer 22 can include graphite, such as a layer of carbon deposited on the p-layer followed by one or more layers of metal, such as the metals described above. The back contact layer 22, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 22, can be from about 0.1 μm to about 1.5 μm in thickness.

In the embodiment of FIG. 6, an encapsulating glass 24 is shown on the back contact layer 22.

Other components (not shown) can be included in the exemplary module 10, such as bus bars, external wiring, laser etches, etc. The module 10 may be divided into a plurality of individual cells that are connected in series in order to achieve a desired voltage, such as through an electrical wiring connection. Each end of the series connected cells can be attached to a suitable conductor, such as a wire or bus bar, to direct the photovoltaically generated current to convenient locations for connection to a device or other system using the generated electric. A convenient means for achieving the series connected cells is to laser scribe the module 10 to divide the device into a series of cells connected by interconnects. Also, electrical wires can be connected to positive and negative terminals of the PV module 10 to provide lead wires to harness electrical current produced by the PV module 10.

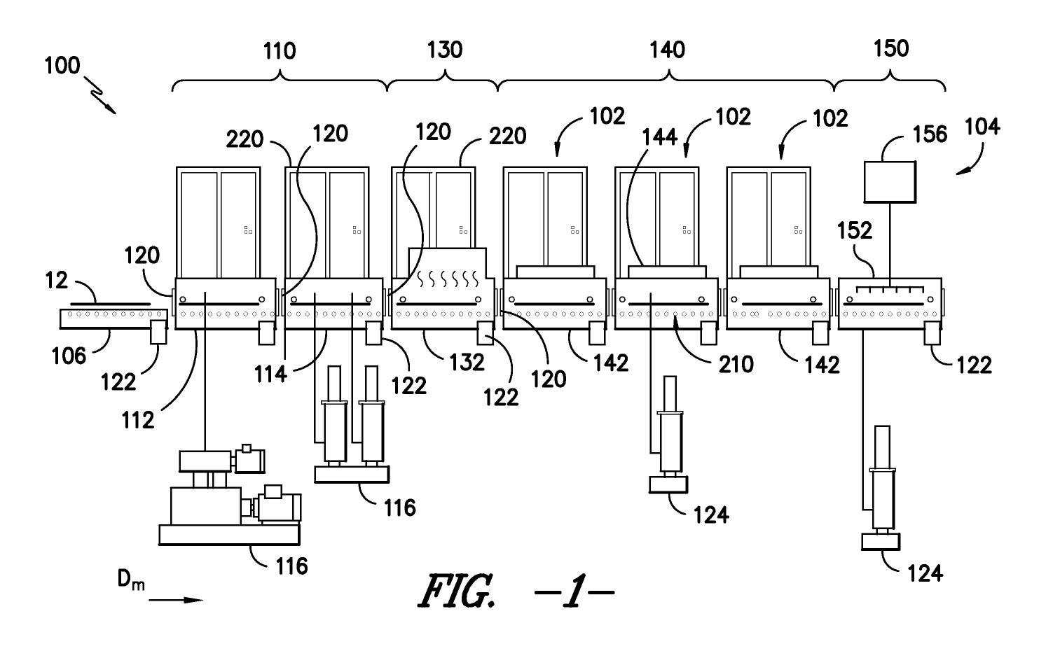

Referring now to FIG. 1, one embodiment of a system for forming a thin film PV device is illustrated. The system 100 may include, for example, one or more annealing apparatus 102 and one or more quenching apparatus 104. The annealing apparatus 102 and quenching apparatus 104 may be sequentially positioned within the system 100 to at least partially form a thin film PV device 10. For example, the annealing apparatus 102 and quenching apparatus 104 may respectively anneal and quench a thin film photovoltaic sub-device during forming of the device 10. A sub-device according to the present disclosure includes various layers of the device 10 before completion of the device 10. For example, a sub-device may include a glass substrate 12 and a TCO layer 14 deposited thereon. Deposition of the TCO layer 14 on the glass substrate 12 may occur before annealing of the sub-device by the annealing apparatus 102. Further, annealing and quenching by the annealing apparatus 102 and quenching apparatus 104 may occur prior to depositing or otherwise forming of any other layers on the sub-device, such as an RTB layer 16, CdS layer 18, CdTe layer 20, back contact layer 22, or encapsulating glass 24, as discussed above. Thus, the sub-device may comprise only the TCO layer deposited on the glass substrate 12 during annealing and quenching by the annealing apparatus 102 and quenching apparatus 104.

Through annealing and quenching, strength can be added to the sub-device and glass substrate 12 thereof by creating compressive stresses therein, which can help the sub-device and glass substrate 12 thereof endure thermal stress in normal use (e.g., created through temperature variations when deployed in the field) and during processing thereof. This increased strength can, for example, help reduce the occurrence of panel breakage of the resulting PV device once placed in operation in the field. Thus, thinner glass substrates 12 may be able to be used through adding strength to the glass in production of the PV device. For example, the glass substrate 12 can be a borosilicate glass having a thickness of about 0.5 mm to about 2.5 mm, such as about 0.7 mm to about 1.3 mm.

Additionally, quenching may reduce or prevent warping of the glass substrate 12 during the production process. In particular, the speed and uniformity of quenching according to the present disclosure may reduce or prevent warping despite the use of increasingly high annealing temperatures.

As shown in FIG. 1, during forming of devices 10, individual sub-device may be moved through a series of stations, including the annealing apparatus 102 and quenching apparatus 104. The sub-devices as shown are moved through the stations in direction of movement Dₘ. For example, substrate 12 may initially be placed onto a load conveyor 106 and subsequently moved into an entry vacuum lock station 110 that includes a load vacuum chamber 112 and a load buffer chamber 114. A “rough” (i.e., initial) vacuum pump 116 is in communication with the load vacuum chamber 112 to drawn an initial load pressure, and a “fine” (i.e., final) vacuum pump 118 is in communication with the load buffer chamber 114 to increase the vacuum (i.e. decrease the initial load pressure) in the load buffer chamber 112 to reduce the vacuum pressure within the entry vacuum lock station 110. Valves 120 (e.g., gate-type slit valves or rotary-type flapper valves) are operably disposed between the load conveyor 106 and the load vacuum chamber 112, between the load vacuum chamber 112 and the load buffer chamber 114, and between the load buffer chamber 114 and a neighboring station. These valves 120 are sequentially actuated by a motor or other type of actuating mechanism 122 in order to introduce the substrates 12 into the vacuum station 110 in a step-wise manner without affecting the vacuum within the subsequent station.

In operation of the system 10, an operational vacuum is maintained in the system 10 by way of any combination of rough and/or fine vacuum pumps 124. In order to introduce a substrate 12 into the load vacuum station 110, the load vacuum chamber 112 and load buffer chamber 114 are initially vented (with the valve 120 between the two modules in the open position). The valve 120 between the load buffer chamber 114 and the subsequent station is closed. The valve 120 between the load vacuum chamber 112 and load conveyor 106 is opened and a substrate 12 is moved into the load vacuum chamber 112. At this point, the first valve 120 is shut and the rough vacuum pump 116 then draws an initial vacuum in the load vacuum chamber 112 and load buffer chamber 114. The substrate 12 is then conveyed into the load buffer chamber 114, and the valve 120 between the load vacuum chamber 112 and load buffer chamber 114 is closed. The fine vacuum pump 118 then increases the vacuum level in the load buffer chamber 114 to approximately the same vacuum level in the subsequent station. At this point, the valve 120 between the load buffer chamber 114 and subsequent station is opened and the substrate 12 is conveyed into this station.

Thus, the substrates 12 are transported into the exemplary system 10 first through the load vacuum chamber 112 that draws a vacuum in the load vacuum chamber 112 to an initial load pressure. For example, the initial load pressure can be less than about 250 mTorr, such as about 1 mTorr to about 100 mTorr. Optionally, a load buffer chamber can reduce the pressure to about 1×10⁻⁷ Torr to about 1×10⁻⁴ Ton, and can then be backfilled with an inert gas (e.g., argon, nitrogen, etc.) in a subsequent chamber within the system 10 (e.g., within a sputtering deposition chamber) to a deposition pressure (e.g., about 10 mTorr to about 100 mTorr).

In another embodiment, the apparatus is operated in a purged mode. Instead of pumping out atmosphere at the load station and backfilling to a desired pressure with an inert gas, the chamber is continuously filled at or slightly above atmospheric pressure with an inert gas, which thereby keeps atmospheric gases from entering the chamber.

The substrates 12 can then be transported into and through subsequent stations. For example, in some embodiments a substrate 12 may be transferred from the entry vacuum lock station 110 to a deposition station 130. The deposition station 130 may include one or more deposition chambers 132 for depositing a material on the substrates 12. The chambers 132 may deposit, for example, a TCO layer 14 on the glass substrate 12. Deposition in each chamber may be a vapor deposition process, such as sputtering, chemical vapor deposition, physical vapor deposition, or any other suitable vapor deposition or deposition process.

As discussed, an operational vacuum may be maintained in the deposition chamber 130 and various stations 132 thereof through use of vacuum pumps 124 and valves 120. The vacuum pumps 124 and valves 120 may be operated as discussed above to maintain the operational vacuum level during transfer of the substrate 12 to and from the deposition chamber 130 and stations 132 thereof, as well as during treatment thereof.

After the deposition of a TCO layer 14 on the glass substrate 12, the sub-device may be transferred to a heating station 140, which may include one or more annealing apparatus 102. An annealing apparatus 102 may include heating chambers 142 for heating the substrate to an anneal temperature. Each annealing apparatus 102 may further include one or more independently controlled heaters 144. Each heater 144 may be in communication with a heating chamber 142 to heat that chamber 142. Each heater 144 may, for example, define an individual heat zone. A particular heat zone may include one or more heaters 144. One or more heat zones may be defined in each chamber 142. The heating chambers 142 can heat the substrates 14 to an anneal temperature, such as about 600° C. to about 650° C. or any other suitable temperature or range of temperatures that anneal the substrate 14, in order to anneal the substrate 14. When more than one heating chamber 142 or heater 144 is utilized, the substrate may be incrementally heated to the anneal temperature by subsequent heating chambers 142 or heaters 144. Although shown with three heating chambers 142, any suitable number of heating chambers 142 can be utilized.

As discussed, an operational vacuum may be maintained in the annealing apparatus 102 and various stations 142 thereof through use of vacuum pumps 124 and valves 120. The vacuum pumps 124 and valves 120 may be operated as discussed above to maintain the operational vacuum level during transfer of the substrate 12 to and from the annealing apparatus 102 and the various stations 142.

After annealing of the sub-device and glass substrate 12 thereof, the sub-device may be transferred to a quenching station 150. The quenching station 150 may include one or more quenching apparatus 104. A quenching apparatus 104 according to the present disclosure may be generally configured to rapidly cool the sub-device, after annealing, to a quenched temperature. The quenched temperature may be, for example, about 450° C. or less, such as about 425° C. or less, such as about 350° C. or less. Further, such quenching may occur relatively quickly, such as in a quenching time of about 4 seconds to about 30 seconds, such as from about 4 seconds to about 10 seconds. In one particular embodiment, the quenching apparatus 104 is generally configured to cool the sub-device, after annealing, to a quenched temperature of about 350° C. or less, in a quenching time of about 4 seconds to about 7 seconds. Such cooling may lock in compressive stresses within the sub-device, and may further minimize warping thereof.

A quenching gas is provided to a quenching apparatus 104 according to the present disclosure to quench the sub-device. The quenching gas can generally comprise an inert gas (e.g., argon, neon, nitrogen, helium, xenon, radon, etc., or mixtures thereof). Nitrogen may be a particularly advantageous quenching gas. In one particular embodiment, the quenching atmosphere is substantially non-reactive with the TCO layer 14 and/or the substrate 12. For example, the quenching gas can, in one embodiment, consist essentially of an inert gas or mixture of inert gases, and is thus substantially free from oxygen and other reactive gases that could chemically interact with the deposited TCO layer 14 and/or the substrate 12. As used herein, the term “substantially free” means no more than an insignificant trace amount present and encompasses completely free (e.g., 0 molar % up to 0.01 molar %).

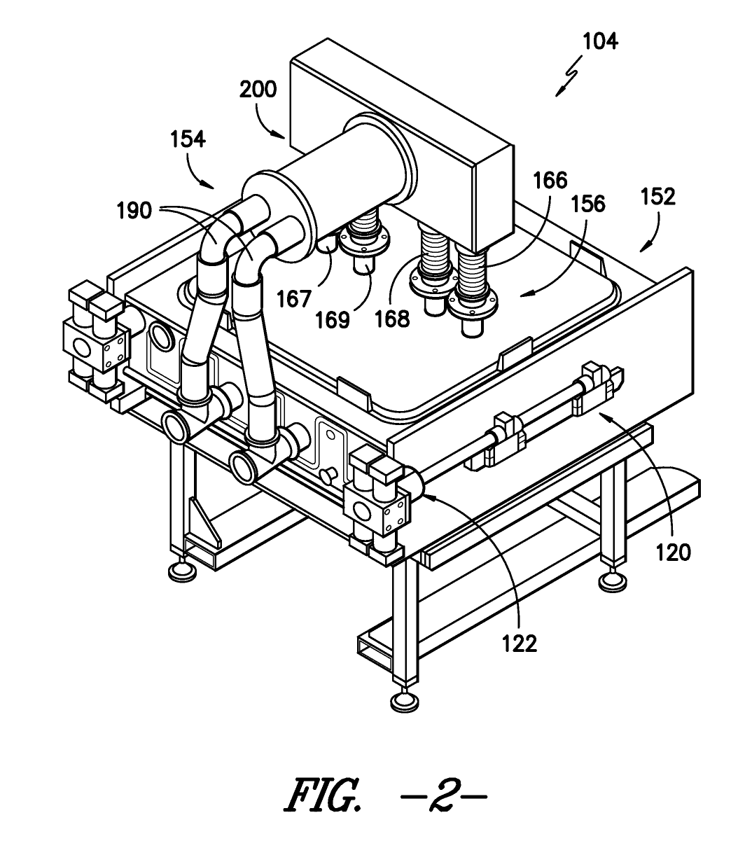

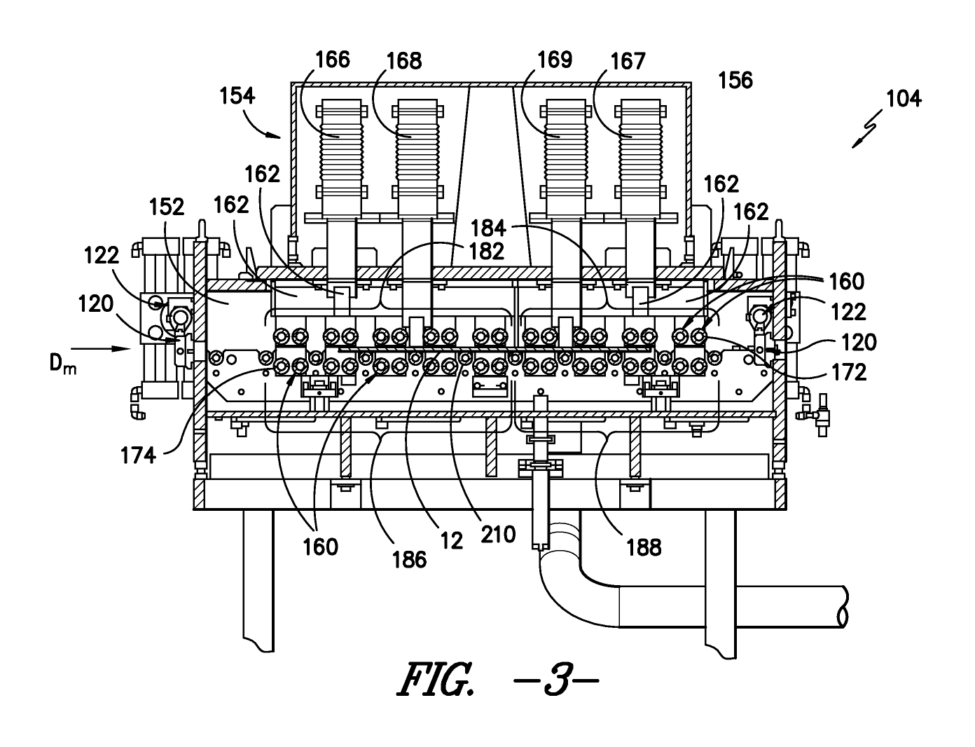

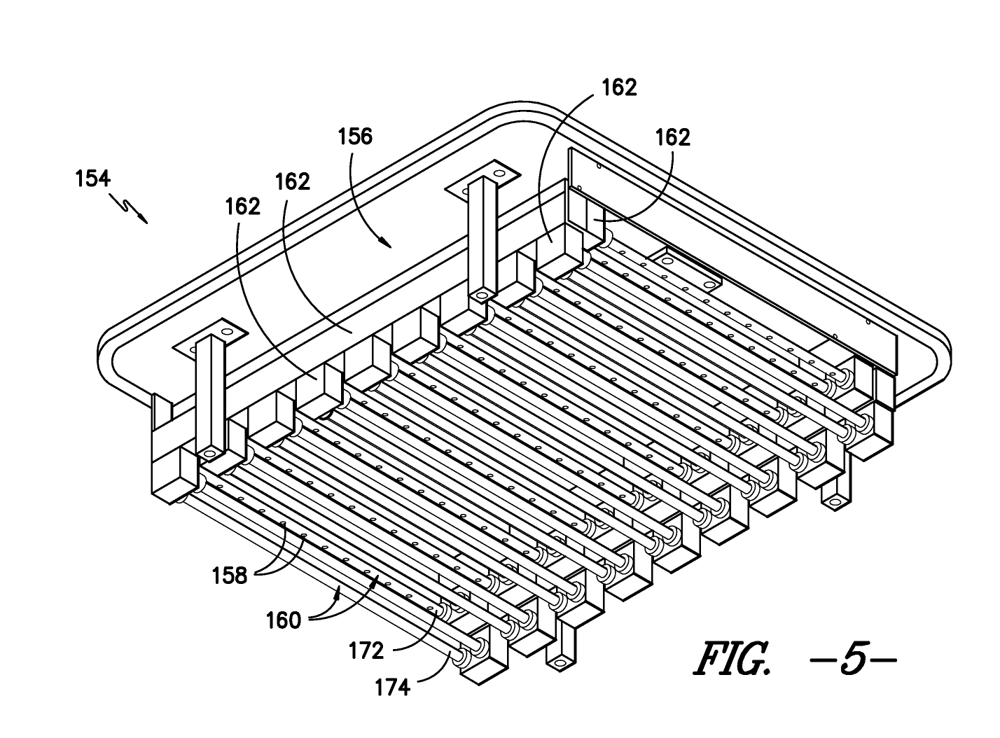

FIGS. 2 through 5 illustrate an exemplary quenching apparatus 104. The quenching apparatus 104 may include a chamber 152 and a quenching system 154. The chamber 152 is a containment vessel that is generally sealed from the external environment. Access to the interior of the vessel for sub-devices may be through valves 120. For example, as shown, a valve 120 may be included on opposing ends of the chamber 152. The valves 120 may each be operated by an actuating mechanism 122, as discussed above. Further, a chamber 152 for a quenching apparatus 104 may adjoin the prior upstream chamber in the direction of movement Dₘ, such as a heating chamber 142 as shown in FIG. 1 or additional quenching apparatus 104. As discussed, an operational vacuum may be maintained in the chamber 152 through use of the valves 120 as well as vacuum pumps 124. The vacuum pumps 124 and valves 120 may be operated as discussed above to maintain the operational vacuum during transfer of the sub-device to and from the chamber 104 of a quenching apparatus 104.

The quenching system 154 may supply the quenching gas to the chamber 152 to quench sub-devices supported therein. For example, the quenching system 154 may include a manifold assembly 156. At least a portion of the manifold assembly 156 is disposed within the chamber 152, and quenching gas is flowed through the manifold assembly 156 to the chamber 152 to quench the sub-device. One or more outlets 158 may be defined in the portion of the manifold assembly 156 disposed in the chamber 152 for the quenching gas to flow through into the chamber 152.

For example, a manifold assembly 156 may include one or more quench tubes 160. The quench tubes 160 may be disposed within the chamber 152. As shown, a plurality of quench tubes 160 may be aligned in rows in the chamber 152, such as in a top row above the sub-device and a bottom row below the sub-device. Further, a longitudinal axis of each tube 160 may extend generally perpendicularly to the direction of movement Dₘ. Outlets 158 may be defined in each quench tube 160, such that quenching gas may be flowed through each tube 160 and into the chamber 160. The outlets 158 may, for example, face the sub-device. In exemplary embodiments, the outlets 158 are positioned such that quenching gas flowed from each quench tube 160 is exhausted through the outlet 158 generally perpendicularly to the surface of the sub-device, such that the quenching gas initially impinges on the sub-device. Such impingement may further facilitate the quenching process.

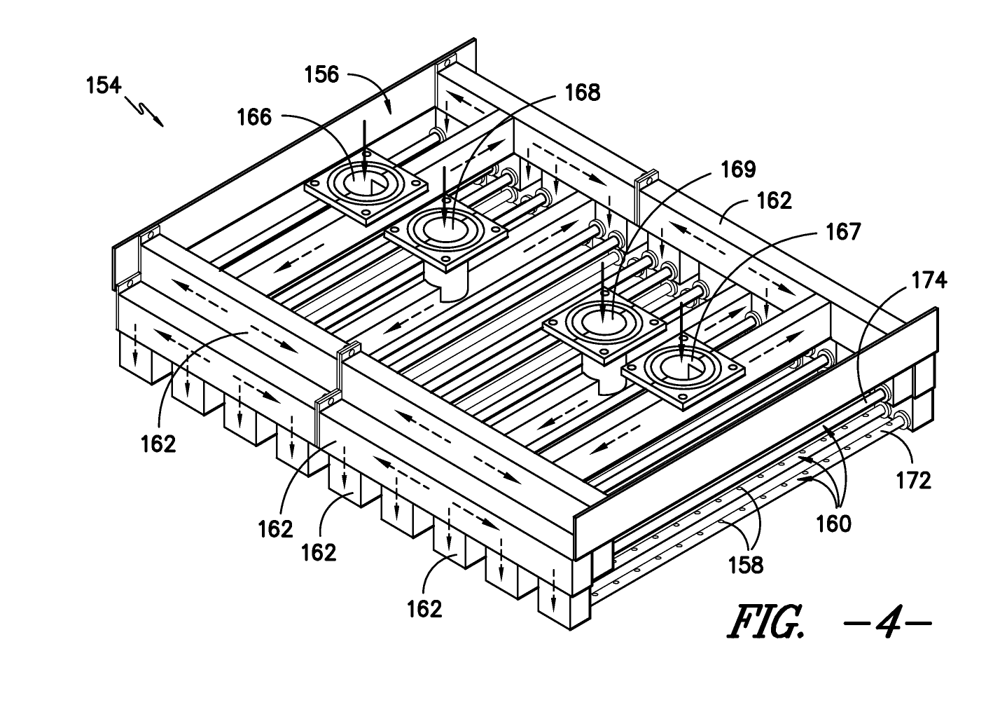

The quench tubes 160 may be fed by pipes 162, which are additionally included in the manifold assembly 156. The pipes 162 may be in fluid communication with the quench tubes 160, and may be used to distribute the quenching gas to the quench tubes 160. An exemplary illustration of the flow of quenching gas through pipes 162 is shown by arrows in FIG. 4. At least a portion of the pipes 162 may be disposed within the chamber 152. The pipes 162 may receive the quenching gas from one or more lead pipes, which may be in fluid communication with the pipes 162 to provide the quenching gas to the chamber 152. As shown, for example, lead pipes included in the manifold assembly 156 may divide it into two or more zones. FIGS. 2 through 5 illustrate, for example, a top upstream lead pipe 166, a top downstream lead pipe 167, a bottom upstream lead pipe 168, and a bottom downstream lead pipe 169. The top upstream lead pipe 166 supplies an upstream portion in the direction of movement Dₘ of the top row of quench tubes 160. The top downstream lead pipe 167 supplies a downstream portion in the direction of movement Dₘ of the top row of quench tubes 160. The bottom upstream lead pipe 168 supplies an upstream portion in the direction of movement Dₘ of the bottom row of quench tubes 160. The bottom downstream lead pipe 169 supplies a downstream portion in the direction of movement Dₘ of the bottom row of quench tubes 160.

The flow of the quenching gas through the various portions of the manifold assembly 156, such as through the various quench tubes 160, can occur simultaneously, in one particular embodiment, in order to inhibit the formation of significant temperature gradients across the surfaces of the sub-device and/or within the thickness of the sub-device during quenching. Alternatively, in another embodiment, the respective flows of the quenching gas through the various portions of the manifold assembly 156, such as through the respective top quench tubes 172 and bottom quench tubes 174 included in the respective top row and bottom row of quench tubes 160, can differ to promote such temperature gradients, e.g., to counteract the presence of a thermal expansion mismatch of a given coating and an underlying glass substrate. The flow rate and flow time can additionally be adjusted based on multiple factors, such as the size of the substrate 12, the amount and speed of cooling desired, etc.

In some embodiments, for example, the manifold assembly 156 and quench tubes 160 thereof may be compartmentalized into zones, such as top upstream zone 182, top downstream zone 184, bottom upstream zone 186, and bottom downstream zone 188. Each zone may be supplied with quenching gas by the respective lead pipe. For example, the top upstream zone 182 of quench tubes 160 may be supplied by the top upstream lead pipe 166. Further, valves (not shown) can respectively control the flow rate of the quenching gas to each of the zones. As such, the flow rate of the quenching gas at different zones can be independently controlled and adjusted. Such control can help to substantially uniformly cool the surfaces of the sub-device across its entire surface area. In one particular embodiment, a suitable controller 220 (see FIG. 1) can monitor the temperature across the surfaces of the sub-device during quenching through the use of a temperature sensor (not shown) and can then adjust the flow rate accordingly in each zone through adjustment of the valves.

In exemplary embodiments, the quenching system 154 is a closed circuit quenching system. In these embodiments, at least a portion of the quenching gas may be recirculated to the chamber 152 after being flowed into the chamber 152 and, after a period of time, flowed out of the chamber 152. For example, exhaust tubes 190 may be included in the quenching system 154 and in fluid communication with the interior of the chamber 152. Quenching gas may be flowed from the chamber 152 into the exhaust tubes 190. In embodiments wherein the quenching system 154 defines a closed circuit, at least a portion of this quenching gas may then be re-circulated to the manifold assembly 156. Additionally or alternatively, however, a portion of the quenching gas may be dumped from the system 154 through exhaust tubes 190, or the system 154 may be open circuit and all quenching gas may be dumped.

A supply source (not shown) may in some embodiments be provided in the quenching system to provide quenching gas thereto. The supply source may be included in both open circuit and closed circuit systems wherein additional quenching gas may be required during operation.

The quenching gas is supplied to the chamber 152 at a quenching temperature below the anneal temperature to quench the sub-device therein to a quenched temperature. The quenching temperature may be, for example, from about 0° C. to about 100° C., such as from about 0° C. to about 80° C. Further, in some embodiments such as when the quenching system 150 is a closed circuit quench system, a heat exchanger 200 may be included. The heat exchanger 200 may cool the quenching gas to the quenching temperature before the gas flows into the chamber 152. For example, as shown in FIG. 2, a heat exchanger 200 may be provided between exhaust tubes 190 and a manifold assembly 156 to cool the quenching gas, and in particular re-circulated quenching gas. The heat exchanger 200 may be any suitable heat exchanger, such as a direct contact, indirect contact, parallel flow, or counter-flow heat exchanger.

As mentioned above, sub-devices may be supported in the chamber 152. In some embodiments, the sub-devices may be supported by an interior surface of the chamber 152 or by a shelf disposed therein. Alternatively, in exemplary embodiments as shown, the sub-devices may be supported by a conveyor 210, which may additionally move the sub-device into, through, and out of the chamber 152. The sub-device may thus be movably supported on the conveyor 210. As shown in FIG. 1, for example, system 100 may include a conveyor system configured to move the sub-device into, through, and out of the various stations. In the illustrated embodiment, this conveyor system includes a plurality of individually controlled conveyors 210 as well as the load conveyor 106, with each of the various chambers in each station including a respective one of the conveyors 210. It should be appreciated that the type or configuration of the conveyors 210 may vary. In the illustrated embodiment, the conveyors 210 are roller conveyors having rotatably driven rollers that are controlled so as to achieve a desired conveyance rate of the sub-device through the respective chamber and the system 100 overall.

As described, each of the various chambers, associated apparatus, and respective conveyors 210 in the system 100 are independently controlled to perform a particular function. For such control, each of the individual chambers and associated apparatus may have an associated independent controller 220 configured therewith to control the individual functions of the respective module. The plurality of controllers 200 may, in turn, be in communication with a central system controller (not shown). The central system controller can monitor and control (via the independent controllers 210) the functions of any one of the chambers and associated apparatus, so as to achieve an overall desired heat-up rate, deposition rate, cool-down rate, conveyance rate, and so forth, in processing of the sub-devices through the system 10.

As discussed, the present disclosure is further directed to a process for forming a thin film PV device 10. The process may include heating a sub-device to an anneal temperature, and quenching the sub-device with a quenching gas to cool the glass substrate 12 to a quenched temperature. The sub-device may include a glass substrate 12 and a TCO layer 14 deposited thereon, and the quenching gas may comprise an inert gas, as discussed above. Annealing may occur, for example, in an annealing apparatus 102. Quenching may occur in, for example, a quenching apparatus 104.

Further, in some embodiments, the process may include re-circulating the quenching gas, as discussed above, and/or cooling the quenching gas to a quenching temperature, as discussed above.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A process of forming a thin film photovoltaic device, the process comprising:
heating a thin film photovoltaic sub-device to an anneal temperature, the thin film photovoltaic sub-device comprising a glass substrate and a transparent conductive oxide deposited on the glass substrate; and,
quenching the thin film photovoltaic sub-device with a quenching gas to cool the thin film photovoltaic sub-device to a quenched temperature, wherein the quenching gas comprises an inert gas.

2. The process of claim 1, wherein the anneal temperature is about 600° C. to about 650° C.

3. The process of claim 1, wherein the quenched temperature is about 450° C. or less.

4. The process of claim 1, wherein the quenching gas has a quenching temperature of about 0° C. to about 100° C.

5. The process of claim 1, wherein the quenching gas comprises nitrogen.

6. The process of claim 1, wherein the quenching gas is substantially free from oxygen.

7. The process of claim 1, wherein the glass substrate comprises borosilicate glass.

8. The process of claim 7, wherein the glass substrate has a thickness of about 0.5 mm to about 2.5 mm.

9. The process of claim 1, wherein the transparent conductive oxide comprises cadmium tin oxide.

10. The process of claim 1, further comprising re-circulating the quenching gas.

11. The process of claim 1, further comprising cooling the quenching gas to a quenching temperature.

12. A system for forming a thin film photovoltaic device, the system comprising:
a chamber generally sealed from an external environment; and,
a quenching system supplying a quenching gas to the chamber to quench a thin film photovoltaic sub-device supported within the chamber, the quenching system comprising a manifold assembly, at least a portion of the manifold assembly disposed within the chamber and defining at least one outlet for the quenching gas to flow therethrough into the chamber,
wherein the quenching gas comprises an inert gas.

13. The system of claim 12, wherein the quenching system is a closed circuit quenching system.

14. The system of claim 12, wherein the quenching system further comprises a heat exchanger.

15. The system of claim 12, wherein quenching gas exhausted from the at least one outlet impinges on the thin film photovoltaic sub-device.

16. The system of claim 12, further comprising a plurality of outlets.

17. The system of claim 16, wherein the manifold assembly comprises a plurality of quench tubes, each of the plurality of quench tubes disposed within the chamber and defining at least one of the plurality of outlets.

18. The system of claim 17, wherein the plurality of quench tubes comprise a plurality of top quench tubes and a plurality of bottom quench tubes.

19. The system of claim 12, further comprising a conveyor disposed within the chamber for movably supporting the thin film photovoltaic sub-device.

20. The system of claim 12, further comprising a heating chamber adjoining the chamber.
